(19) United States
(12) Patent Application Publication
(10) Pub. No.: US 2025/0266231 A1
(43) Pub. Date: Aug. 21, 2025

(54) VAPORIZER, METHOD, AND ION SOURCE INCLUDING VAPORIZER

(71) Applicant: NISSIN ION EQUIPMENT CO., LTD., Koka-city (JP)

(72) Inventors: Sami K. Hahto, Nashua, NH (US); George Sacco, Groveland, MA (US)

(73) Assignee: NISSIN ION EQUIPMENT CO., LTD., Koka-city (JP)

(21) Appl. No.: 19/197,199

(22) Filed: May 2, 2025

Related U.S. Application Data
(63) Continuation of application No. 18/621,274, filed on Mar. 29, 2024.
(63) Continuation of application No. 17/945,705, filed on Sep. 15, 2022, now Pat. No. 12,328,807.

(51) Int. Cl. H01J 37/08; H01J 37/317; H01J 37/32

(52) U.S. Cl. CPC H01J 37/08; H01J 37/3171; H01J 37/3244; H01J 37/32467; H01J 37/32522

(57) ABSTRACT

A vaporizer includes a crucible in which a solid material is received, the crucible including a reactive gas inlet and a vapor outlet.

### CROSS-REFERENCE TO RELATED APPLICATIONS

This application is a continuation of U.S. application Ser. No. 18/621,274 filed on Mar. 29, 2025 and U.S. application Ser. No. 17/945,705 filed on Sep. 15, 2022, the disclosures of each of which being herein incorporated by reference in their entireties.

### BACKGROUND

The present disclosure relates to an ion source and, in particular, an ion source having a plenum chamber and plenum plate with longitudinal aperture, and an ion implanter having the same.

Ion sources generate a plasma from which an ion beam is extracted. The extracted ion beam is then directed onto a target, e.g., a wafer, in order to implant various ions into the target to dope the target with the ions.

The ion beam may be a spot beam or a ribbon ion beam. A spot beam has an elliptical cross-section when the ion beam is cut in a plane perpendicular to a traveling direction of the ion beam. A ribbon beam has a rectangular cross-section (i.e., a vertical length that is greater than a horizontal length) when the ion beam is cut in a plane perpendicular to the traveling direction of the ion beam. In either case, it is advantageous for the ion source to produce a plasma from which a uniform ion beam may be extracted to efficiently implant the ions into the target.

### SUMMARY

It is an aspect to provide a ion source which achieves improved uniformity of the plasma when generating a ribbon ion beam.

According to an aspect of one or more embodiments, there is provided a vaporizer comprising a crucible in which an solid material is received, the crucible comprising a reactive gas inlet and a vapor outlet.

According to another aspect of one or more embodiments, there is provided a method for generating a vapor, the method comprising preparing a solid material in a crucible; and introducing a reactive gas into the crucible.

According to yet another aspect of one or more embodiments, there is provided an ion source comprising a first gas source comprising a first gas that contains a reactive component; a vaporizer comprising a crucible containing a solid material, the crucible comprising a gas inlet communicatively connected to the first gas source, and a vapor outlet; and an arc chamber configured to generate a plasma therein. The vapor outlet of the vaporizer is configured to output a vapor into the arc chamber through a wall of the arc chamber.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic plan view of an example of an ion implanter, according to some embodiments;

FIG. 2 illustrates an exploded perspective view of an example of a ion source of the ion implanter, according to some embodiments;

FIGS. 3-5 illustrate a ion source, according to some embodiments, in which FIG. 3 illustrates the ion source when viewed from a Z-axis direction, FIG. 4 illustrates a cross-sectional view of the ion source taken along A-A′ in FIG. 3, and FIG. 5 illustrates a cross-sectional view of the ion source taken along B-B′ in FIG. 3;

FIGS. 6-8 illustrate a ion source, according to some embodiments, in which FIG. 6 illustrates the ion source when viewed from a Z-axis direction, FIG. 7 illustrates a cross-sectional view of the ion source taken along A-A′ in FIG. 6, and FIG. 8 illustrates a cross-sectional view of the ion source taken along B-B′ in FIG. 6;

FIG. 9 illustrates an example of a nozzle of a vaporizer of the ion source, according to some embodiments.

FIG. 10 illustrates an example of a heater of the ion source, according to some embodiments;

FIGS. 11-13 illustrate a liner of the ion source, according to some embodiments, in which FIG. 11 illustrates the liner when the ion source is viewed from a Z-axis direction in FIG. 2, FIG. 12 illustrates a cross-sectional view of the liner taken along A-A′ in FIG. 11, and FIG. 13 illustrates a cross-sectional view of the liner taken along B-B′ in FIG. 11;

FIGS. 14-16 illustrate a liner of the ion source, according to some embodiments, in which FIG. 14 illustrates the liner when the ion source is viewed from a Z-axis direction in FIG. 2, FIG. 15 illustrates a cross-sectional view of the liner taken along A-A′ in FIG. 14, and FIG. 16 illustrates a cross-sectional view of the liner taken along B-B′ in FIG. 14;

FIG. 17 illustrates an ion source of the ion implanter according to some embodiments; and

FIG. 18 illustrates an ion source of the ion implanter according to some embodiments.

### DETAILED DESCRIPTION

As used in this specification, a phrase of the form “at least one of A, B, or C” includes within its scope “only A”, “only B”, “only C”, “A and B”, “B and C”, “A and C” and “A, B, and C”.

In a related art ion source, one or more gases and/or vapors are injected into a plasma chamber of the ion source to generate the plasma inside the plasma chamber. In a related art technology, a plenum is used to generally distribute the gas or vapor throughout an arc chamber. However, the plenum in the related art technology is used to distribute gases or vapor to produce an efficient reaction with a filament, and does not take into account properties of the ion beam. For example, the related art technology does not take into account differences between plasma generated to produce a spot beam verses a ribbon ion beam. In particular, in the case of a ribbon ion beam, it is advantageous for the one or more gases and/or vapors to be uniformly dispersed longitudinally within a plasma chamber so that a plasma density is uniform in a longitudinal direction within the plasma chamber in order to be able to extract a consistent ribbon ion beam to effectively dope the target.

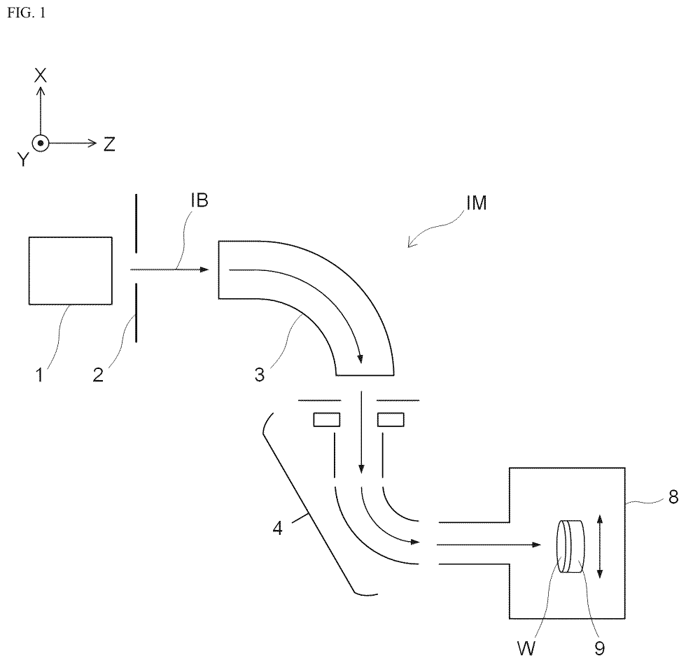

FIG. 1 is a schematic plan view of an example of an ion implanter IM, according to some embodiments. The ion implanter IM illustrates an example of a use case of the ion source. The ion implanter IM is only an example and, in some embodiments, the ion source may be used in any device requiring ion generation.

In an embodiment, the ion implanter IM may include a ion source 1, one or more extraction electrodes 2, a mass analyzer 3, an E-bend device 4, a process chamber 8, and a wafer holder 9. However, these components are only an example and, in some embodiments, a greater or lesser number of components may be included in the ion implanter IM.

In an embodiment, the ion source 1 may be an indirect hot cathode (IHC) ion source. However, embodiments are not limited thereto and, in some embodiments, other types of ion source may be used. In the description that follows, the ion source 1 is described under the assumption that ion source 1 is an IHC ion source. The ion source 1 generates plasma, which is a source of an ion beam IB. The one or more extraction electrodes 2 extract the ion beam IB from the plasma generated in the ion source 1. In some embodiments, the one or more extraction electrodes 2 may include a plurality of extraction electrodes 2.

The ion beam IB extracted from the extraction electrode 2 contains a plurality of ions. The mass analyzer 3, which is an electromagnet, selects the ions according to their mass to extract desired ions from the ion beam IB. The E-bend device 4 accelerates or decelerates and bends the ion beam IB including ions selected by mass analyzer 3 to convert the ion beam IB into an ion beam IB having a desired energy.

The ion beam IB having the desired energy is then irradiated onto a wafer W that is held by a wafer holder 9. By moving the wafer holder 9 (and thus the wafer W) across the ion beam IB, an ion implantation process may be carried out on the wafer W.

The wafer W held by the wafer holder 9 is placed in the process chamber 8. A drive device (not illustrated) is connected to the wafer holder 9. The drive device may adjust a posture of the wafer holder 9 with respect to the ion beam IB to adjust an irradiation angle of the ion beam IB with respect to the wafer W.

The XYZ axes shown in FIG. 1 are drawn such that the Z axis is parallel to the traveling direction of the ion beam IB; the X and Y axes are mutually orthogonal to the Z axis. The direction of each of the XYZ axes for any individual component varies according to an orientation of a component with respect to the ion beam being transported as illustrated in FIG. 1.

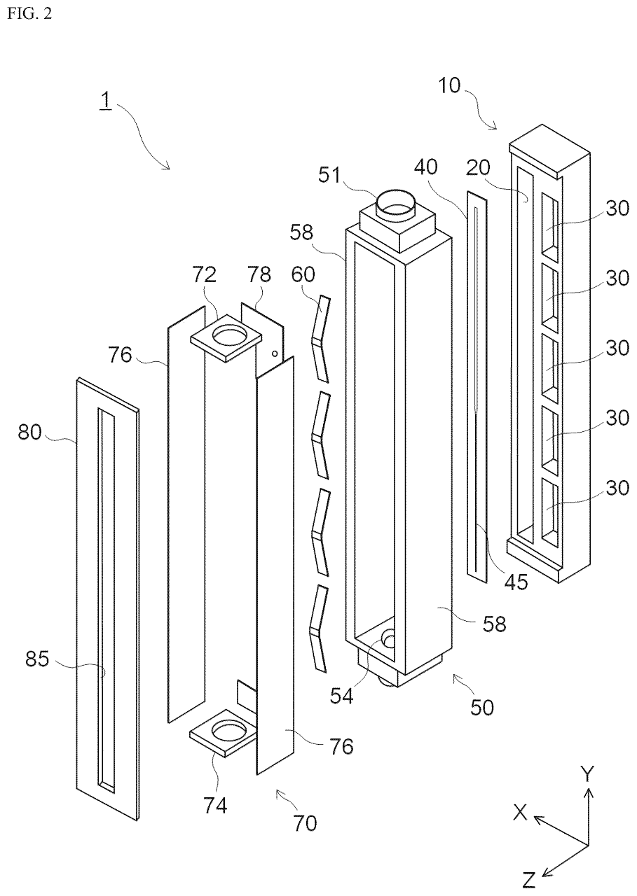

FIG. 2 illustrates an exploded perspective view of an example of a ion source of the ion implanter, according to some embodiments.

In an embodiment, the ion source 1 may include a plenum 10 and an ionization chamber 50. The plenum 10 may include a plenum chamber 20, a plurality of gas feed chambers 30, and a plenum plate 40. The plenum chamber 20 is rectangular, having a long side in a vertical direction (e.g., a Y-axis direction) and a short side in a horizontal direction (e.g., a X-axis direction). In other words, the plenum chamber 20 may be a longitudinal chamber having a width in the X-axis direction and height in the Y-axis direction that is greater than the width. In an embodiment, the plenum chamber 20 includes a plurality of walls that, along with the plenum plate 40, define the plenum chamber 20. In an embodiment, the plenum chamber 20 has an opening in a distal side thereof and the opening is covered by the plenum plate 40. The plenum plate 40 has a slit 45 therein. The slit 45 is long in the vertical direction (e.g., the Y-axis direction) and narrow in the horizontal direction (e.g., the X-axis direction) and thus forms a longitudinal aperture in the plenum plate 40. Examples of the slit 45 are described in more detail below.

The plurality of gas feed chambers 30 are formed adjacent to the plenum chamber 20. In an embodiment, the plurality of gas feed chambers 30 are spaced apart from each other in the vertical direction (e.g., the Y-axis direction). In an embodiment, each of the gas feed chambers 30 may be generally rectangular, having a long side in a vertical direction (e.g., a Y-axis direction) and a short side in a horizontal direction (e.g., a X-axis direction). Each of the gas feed chambers 30 may have an opening in a distal end thereof, similar to the plenum chamber 20. In an embodiment, a surface in which the openings of the plurality of gas feed chambers 30 may be formed may be coplanar with the plenum plate 40. In an embodiment, a surface in which the openings of the plurality of gas feed chambers 30 are provided may be coplanar with a surface in which the opening of the plenum chamber 20 is provided.

The embodiment of FIG. 2 shows the plenum 10 as formed from a single block. However, in some embodiments, the plenum 10 may be formed in two separate blocks and the two separate blocks may be fixed together. In other words, the plenum chamber 20 may be formed in a first block and the plurality of gas feed chambers 30 may be formed in a second block, and the first and second blocks may be secured together side-by-side. However, it is advantageous to form the plenum 10 from a single block in terms of decreased manufacturing cost and decreased complexity.

In an embodiment, each of the plenum 10 and the plenum plate 40 may be made of carbon. However, this is only an example and, in other embodiments, each of the plenum 10 and the plenum plate 40 may be made of graphite or other materials.

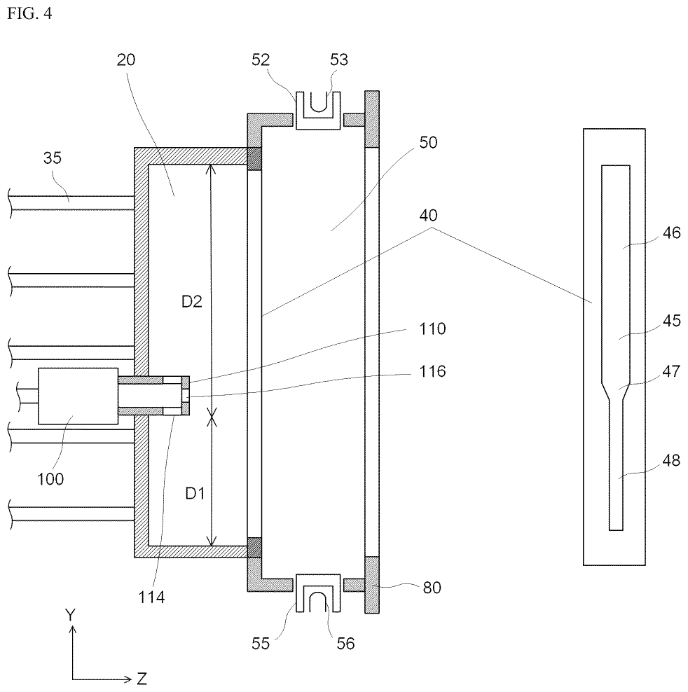

In an embodiment, the ionization chamber 50 may include a top wall 51 including a top hole for receiving a cathode 52 and a filament 53 (see FIG. 4), a bottom wall 54 including a bottom hole for receiving a cathode 55 and a filament 56 (see FIG. 4), and two side walls 58 that connect the top wall to the bottom wall. The front and the back of the ionization chamber 50 in a third direction (e.g., a Z-axis direction), which is a traveling direction of an ion beam that is extracted from the ion source 1, are open. The ionization chamber 50 is rectangular, having a long side in a vertical direction (e.g., a Y-axis direction) and a short side in a horizontal direction (e.g., a X-axis direction). In other words, similar to the plenum chamber 20, the ionization chamber 50 may be a longitudinal chamber having a width in the X-axis direction and height in the Y-axis direction that is greater than the width. It is noted that the cathode 52 and the filament 53 are described as being received in the top hole of the ionization chamber 50 and the cathode 55 and filament 56 are described as being received in the bottom hole of the ionization chamber 50 in FIG. 1. However, this is only an example and, in some embodiments, the positions of the cathode 52 and the filament 53, and the cathode 55 and the filament 56 may be changed.

The ionization chamber 50 is secured to the plenum 10 at a proximal end of the ionization chamber 50 and a distal end of the ionization chamber 50 is covered by an extraction plate 80. In other words, the back of the ionization chamber 50 is secured to the plenum 10 such that an interior of the plenum chamber 20 is in fluid communication with an interior of the ionization chamber 50 and such that an interior of each of the plurality of gas feed chambers 30 is in fluid communication with the interior of the ionization chamber 50. The front of the ionization chamber 50 is covered by the extraction plate 80. The extraction plate 80 has an extraction aperture 85 therein. The extraction aperture 85 is long in the vertical direction (e.g., the Y-axis direction) and narrow in the horizontal direction (e.g., the X-axis direction) and thus forms a longitudinal aperture in the extraction plate 80. In an embodiment, the extraction aperture 85 has a uniform width along the vertical direction (e.g., Y-axis direction) thereof.

In some embodiments, interior walls of the ionization chamber 50 may be covered by a liner 70. In some embodiments, the liner 70 may include a plurality of liners. The plurality of liners may include a top liner 72, a bottom liner 74, and two side wall liners 76, which correspond respectively to the top wall 51, bottom wall 54, and two side walls 58 of the ionization chamber 50, and a rear liner 78. The rear liner 78 is formed with an opening corresponding to the slit 45 in the plenum plate 40 and openings corresponding to the plurality of gas feed chambers 30. In some embodiments, the plurality of liners may further include a front liner that is formed with an opening corresponding to the extraction aperture 85 in the extraction plate 80. Examples of the liner 70 will be described in more detail below.

In an embodiment, the liner 70 may be held in place by a spring 60. In an embodiment, the spring 60 may include a plurality of leaf springs as illustrated in the example of FIG. 1. However, this is only an example and, in some embodiments, the spring 60 may include a plurality of coil springs.

In some embodiments, the liner 70 may be omitted.

In use, the plenum chamber 20 receives a vapor from a single point source and provides a space for the vapor to spread out evenly along the height of the ion source 1. In other words, the vapor may broaden and diverge in a longitudinal direction (e.g., a Y-axis direction) within the plenum chamber 20. The plenum plate 40 restricts the flow of vapor from the single point source. The shape of the slit 45 is a longitudinal aperture and is used to produce vertical uniformity of the flow of the vapor into the ionization chamber 50. Each of the plurality of gas feed chambers 30 receives a gas from one or more of a plurality of gas feed lines 35 (not illustrated in FIG. 2) and allows the received gas to spread out before entering the ionization chamber 50. In the ionization chamber 50, a plasma based on the vapor and the gases is generated and the ion beam IB is extracted by the extraction electrodes 2 outside the extraction plate 80 of the ionization chamber 50. The liner 70 prevents sputtering of a plasma generated in the ionization chamber 50 onto the walls of the ionization chamber 50, and thus may increase the time needed between cleanings of the ionization chamber 50, thus saving maintenance costs. In some embodiments, the liner 70 may prevent reaction of the plasma with the walls of the ionization chamber 50.

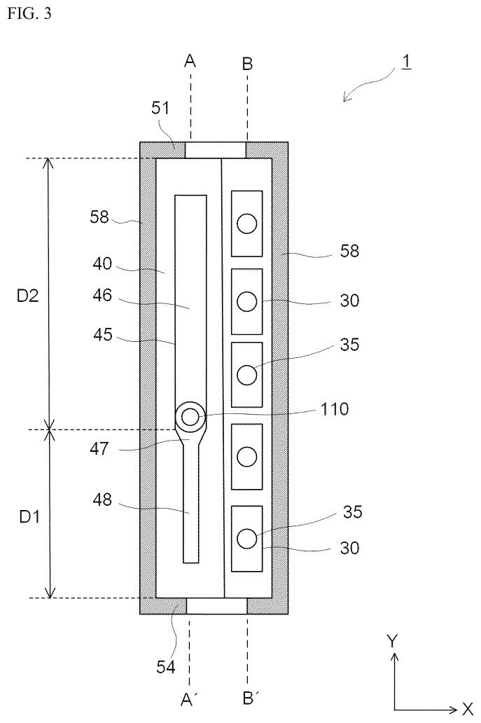

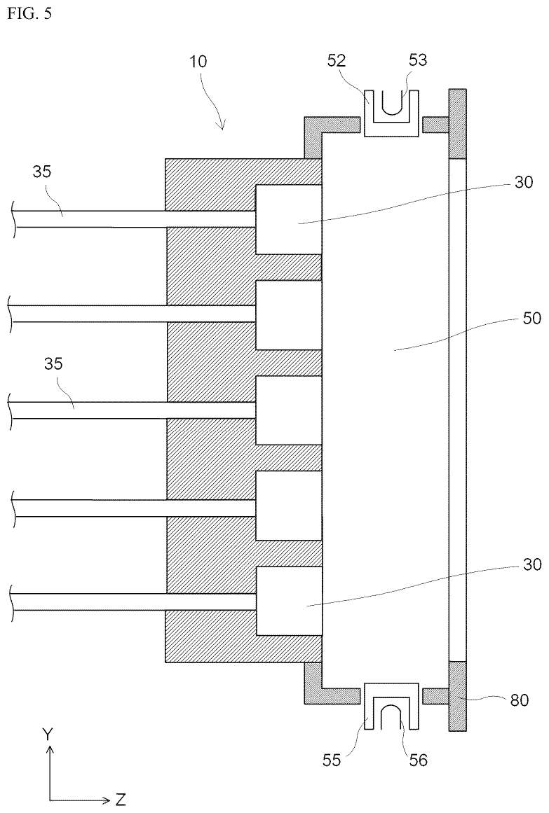

FIGS. 3-5 illustrate the ion source 1, according to some embodiments, in which FIG. 3 illustrates the ion source 1 when viewed from a Z-axis direction with the extraction plate 80 removed, FIG. 4 illustrates a cross-sectional view of the ion source 1 taken along A-A′ in FIG. 3, and FIG. 5 illustrates a cross-sectional view of the ion source 1 taken along B-B′ in FIG. 3. In FIGS. 3-5, like reference designators represent like components in FIG. 2 that have like structure and functions, and therefore a repeated description thereof is omitted for conciseness.

As illustrated in FIGS. 3-5, in an embodiment, the plenum 10 includes the plurality of gas feed chambers 30, each having a corresponding gas feed line 35. In other words, the plurality of gas feed lines 35 feed gases respectively into corresponding ones of the plurality of gas feed chambers 30. The gas feed lines 35 feed various gases into the ionization chamber 50 for generating the plasma in the ionization chamber 50. For example, in some embodiments, the gases may include tungsten fluoride (WF₆), hydrogen (H₂) co-gas, boron trifluoride (BF₃), arsine (AsH₃), phosphine (PH₃), a noble gas such as Argon, Helium and Xenon and/or chlorine (Cl₂), etc. However, these are only examples and, in some embodiments, any gas suitable for generating plasma may be used.

In an embodiment, the ion source 1 includes a vaporizer 100 for generating the vapor, and a nozzle 110 for introducing the vapor into the plenum chamber 20. The vaporizer 100 may be, for example, a vaporizer as described in U.S. application Ser. No. 18/585,499, filed Feb. 23, 2024, and titled “VAPORIZER AND ION SOURCE”; U.S. patent application Ser. No. 17/714,491, filed Apr. 6, 2022, now U.S. Pat. No. 12,112,915 for “VAPORIZER, ION SOURCE AND METHOD FOR GENERATING ALUMINUM-CONTAINING VAPOR”; or U.S. patent application Ser. No. 17/945,705, filed Sep. 15, 2022, now U.S. Patent Application Publication No. 2024/0098869 for “VAPORIZER, ION SOURCE AND METHOD FOR GENERATING ALUMINUM-CONTAINING VAPOR”, the entire contents of each of these U.S. patent applications being herein incorporated by reference in their entireties. In some embodiments, the vaporizer 100 may generate the vapor from a solid raw material. For example, in some embodiments, the solid raw material may be aluminum (Al). However, this is only an example and, in some embodiments, other solid raw materials may be used depending on the vapor used to generate the plasma for extracting the ion beam. In some embodiments, the vaporizer 100 may generate the vapor from antinomy (Sb), sulfur(S) containing compounds, InI₃, InCl₃, WCl₄, Al₂O₃, AlCl₃, Ti (Titanium), Ni (Nickel), or molybdenum disulfide (MoS2) alone or in combination with one or more gasses. However, these are only examples and, in some embodiments, the vaporizer 100 may generate the vapor from other materials and/or gasses.

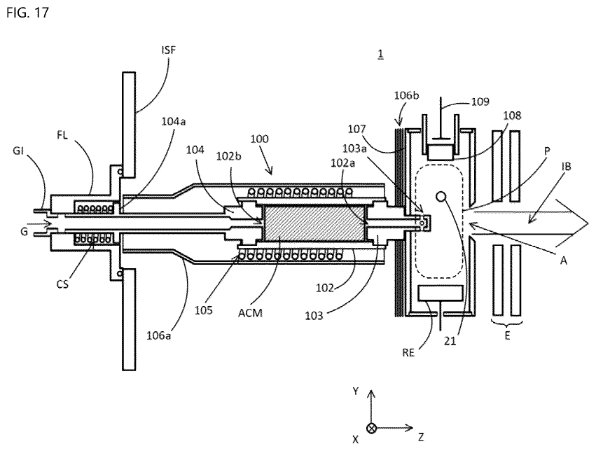

For example, the vaporizer 100 may be included in the ion source 1 as illustrated in FIG. 17. A plasma P may be generated based on an aluminum-containing vapor in an arc chamber 107. An ion beam IB containing aluminum ions is extracted by extraction electrodes E through an aperture A of the arc chamber 107. While two extraction electrodes E having an aperture respectively are illustrated in FIG. 17, the number of extraction electrodes E is exemplary. In some embodiments, the number of extraction electrodes may be more or less than two. Generally, the number of the extraction electrodes may be changed depending on a configuration of the ion source. The vaporizer 100 may be equipped with a crucible 102 in which an aluminum-containing material ACM is placed.

The crucible 102 illustrated in FIG. 17 is a cylindrical member that is longer in one direction. For example, as shown in FIG. 17, an axis of the crucible 102 may extend along a longitudinal direction (e.g., the Z-axis direction in FIG. 17). One end of the crucible 102 in the longitudinal direction has a vapor outlet 102a for supplying aluminum-containing vapor to the arc chamber 107, and the other end of the crucible 102 in the longitudinal direction has a gas inlet 102b to deliver a chlorine containing gas into the crucible 102. In some embodiments, the chlorine containing gas may be, for example, a chlorine gas (Cl₂) or hydrogen chloride gas (HCl).

In some embodiments, a first nozzle 103 and a second nozzle 104 may be removably attached to the crucible 102. The first nozzle 103 and the second nozzle 104 are respectively a roughly elongated cylindrical member. In some embodiments, the first nozzle 103, the second nozzle 104, and the crucible 102 may be made of graphite. However, graphite is only an example and, in some embodiments, another material may be used. The second nozzle 104 includes a portion located on the opposite end of the crucible 102 from the first nozzle 103, and a long cylindrical portion that extends in the −Z axis direction to the end of the ion source 1. Various methods (e.g., fitting and/or screwing) may be used to attach the first nozzle 103 and the second nozzle 104 to the crucible 102. The first and second nozzles 103 and 104 are used to extend a vapor outlet 102a and a gas inlet 102b of the crucible 102.

In FIG. 17, arrow G denotes a flow of a supply of chlorine containing gas. The chlorine containing gas passes through the second nozzle 104, the crucible 102, and the first nozzle 103 and into the arc chamber 107, in that order. In the crucible 102, the chlorine containing gas reacts with the aluminum-containing material ACM that is heated to a high temperature to generate aluminum-containing vapor including aluminum chloride (AlCl₃) and other aluminum particles. The aluminum-containing vapor and chlorine containing gas are fed from crucible 102 to arc chamber 107 through the first nozzle 103.

In some embodiments, the aluminum-containing material ACM may be in the form of a powder, pellets, and/or a block. In the case in which the aluminum-containing material ACM is provided in the form of a block, the aluminum-containing material ACM may have a plurality of pores so that a chemical reaction with the chlorine containing gas may be increased, since the chemical reaction depends on a size of a contact area between the chlorine containing gas and the aluminum. In some embodiments, the aluminum-containing material ACM may be, for example, pure aluminum, aluminum nitride, or aluminum oxide, or other aluminum containing materials including a powder.

In some embodiments, the aluminum-containing material ACM may be pure aluminum. Pure aluminum increases an aluminum ratio of the aluminum-containing vapor, and also increases an ion beam current of the ion beam extracted from the ion source IS. However, embodiments are not limited to pure aluminum, and in some embodiments, aluminum nitride, aluminum oxide and/or other solid aluminum containing materials may be used.

The supply of chlorine containing gas G to the second nozzle 104 may be done through a gas source inlet GI fitted inside of the second nozzle 104, as shown in FIG. 17. For example, in some embodiments, the chlorine containing gas G may be supplied from a gas source configured to supply the chlorine containing gas. The specific configuration of the gas source is not particularly limited as long as the gas source is capable of supplying a chlorine containing gas to the gas source inlet GI. In some embodiments, the crucible 102, the first nozzle 103, the second nozzle 104 and other components that serve as flow paths for chlorine containing gas may be made of corrosion-resistant carbon materials.

The end portion 103a of the first nozzle 103, opposite from an end of the first nozzle 103 attached to the crucible 102, protrudes into the arc chamber 107. The end portion 103a has holes for vapor supply in four orthogonal directions so that aluminum-containing vapor may be diffused and supplied in multiple directions inside of the arc chamber 107.

A coil heater 105 with a thermocouple is wound around a periphery of crucible 102. The aluminum-containing material ACM is heated to a high temperature by the heater 105 and reacts with the chlorine containing gas to generate the aluminum-containing vapor. A first heat shield 106a is placed around a periphery of the heater 105 to block heat radiation from the heater 105.

During operation, as the coil heater 105 heats the crucible 102 and thus the aluminum-containing material ACM within the crucible 102, the temperature within the crucible 102 may vary from an ion source end of the crucible 102 (i.e., an end at which the second nozzle 104 is provided) to an opposite end of the crucible 102 (i.e., an end at which the first nozzle 103 is provided) due, at least in part, to heat that is generated by the arc chamber 107 and transferred to an end of the crucible 102 near the arc chamber 107. For example, in some cases, the temperature difference may be about 125 degrees C. The variance of the temperature from one end of the crucible 102 to the other end of the crucible 102 causes the vapor supply from the vaporizer 100 to the arc chamber 107 to become unstable. In some embodiments, the temperature may be controlled by a thermocouple installed at an end of the coil heater 105. However, even with crucible temperature control based on a temperature measured by the thermocouple, the crucible temperature control is not concise due to the large temperature difference from one end of the crucible 102 to the other end of the crucible 102 as discussed above. Therefore, it becomes difficult to achieve a stable vapor supply from the vaporizer 101 to the arc chamber 107.

Accordingly, in some embodiments, the ion source 1 may be provided with a second heat shield 106b as illustrated in FIG. 1. The second heat shield 106b may be provided between the crucible 102 and a side wall of the arc chamber 107 that faces the crucible 102, and may extend radially outward from the first nozzle 103 and parallel to the side wall of the arc chamber 107. In some embodiments, the second heat shield 106b may be secured by screws or other fittings. The second heat shield 106b may function to prevent heat from the arc chamber 107 from heating the end of the crucible 102 that is near the arc chamber 107.

In some embodiments, the second nozzle 104 may have a large diameter section 104a. In some embodiments, a flange FL may be provided to attach the vaporizer 100 to an ion source flange ISF. A coil spring CS may be provided between the flange FL and the large diameter section 104a of the second nozzle 104. The coil spring CS forces vaporizer 100 against a side wall of the arc chamber 107 to prevent aluminum-containing vapor and/or chlorine containing gas from leaking out between the first nozzle 103 and the arc chamber 107. In some embodiments, one or more gaskets (not shown) may also be provided between the vaporizer 100 and the side wall of the arc chamber 107 to prevent gas leakage between the first nozzle 103 and the arc chamber 107, and/or one or more gaskets (not shown) may be provided between the vaporizer 100 and the second heat shield 106b to prevent gas leakage between the vaporizer 100 and the second heat shield 106b. In some embodiments, a damper, for example, a spring clip in the form of a snap ring, may be attached to the first nozzle 103 in order to avoid excess pressure by the elastic force of the coil spring CS. In still other embodiments, a damper, for example, a spring clip, may be provided between the large diameter section 104a of the second nozzle 104 and the inner wall of the heat shield 106a in order to prevent the excess pressure by the elastic force of the coil spring CS. In some embodiments, one or all of one or more gaskets, a snap ring, and/or a spring clip may be provided. It is noted that the gaskets, snap ring and spring clip are only examples and, in other embodiments, different or additional structures may be used. The ion source flange ISF also indirectly supports the arc chamber 107 and other components around the arc chamber 107 such as the filament 109 and the cathode 108 by supporting parts not shown in FIG. 17. In some embodiments, a reflecting electrode RE may be positioned opposite the cathode 108 to repel electrons from the cathode 108. An external electromagnet, which is not shown in FIG. 17, may generate a magnetic field along a direction connecting the cathode 108 and the reflecting electrode RE.

In some embodiments, the aluminum-containing material ACM may substantially fill the interior of the crucible 102 and chlorine containing gas may move through the crucible 102 through the powder or the pellets, or in the case of an aluminum block, through the pores in the block of the aluminum-containing material ACM. Thus, the chlorine containing gas may escape through the aluminum and be reduced.

In other embodiments, the aluminum-containing material may fill only a portion of the interior of the crucible 102. For example, in some embodiments, a top edge of the aluminum-containing material ACM may coincide with a bottom edge of the vapor outlet 102a. In some embodiments, the aluminum-containing material ACM may be a semi-circular material in cross section, and a top edge of the aluminum-containing material ACM may coincide with a bottom edge of the gas inlet 102b. With this configuration, the chlorine containing gas may flow along the surface of the aluminum-containing material ACM rather than through pores in the aluminum-containing material ACM or between pellets of the aluminum-containing material ACM, allowing the chlorine containing gas to flow more freely to react with the aluminum-containing material ACM. That is, with a configuration in which the aluminum-containing material ACM is provided in a semi-circular cross-section, a reaction between chlorine containing gas and the aluminum-containing material ACM may be accelerated. As example of an aluminum-containing material ACM that is provided in a semi-circular cross-section is illustrated in U.S. application Ser. No. 17/714,491, filed Apr. 6, 2022, now U.S. Pat. No. 12,112,915 for “VAPORIZER, ION SOURCE AND METHOD FOR GENERATING ALUMINUM-CONTAINING VAPOR”, the entire contents of which being herein incorporated by reference. During operation of the ion source IS, a temperature of the extraction electrodes E becomes around 400-500 Celsius. There are no deposits formed on a surface of the extraction electrodes E, based on aluminum chloride which is main ingredient of aluminum-containing vapor, because the boiling point of aluminum chloride included in aluminum-containing vapor is around 180 Celsius. Therefore, in the ion source 1 according to various embodiments described above, the insulation issue with the extraction electrodes E becoming insulated over time and requiring cleaning is avoided. That is, with ion source IS according to various embodiments, it is not necessary to use hydrogen gas in a method such as the “H₂ Co-gas” method to avoid the insulation issue of the extraction electrodes E becoming insulated over time as in the related art.

The above description is provided using an example of an IHC ion source. However, an IHC source is only one example embodiment and, in other embodiments, other types of ion sources such as a Bernas ion source and a Radio frequency inductively coupled plasma ion source, etc. may be used as the ion source IS.

Ion species other than aluminum ions may also be used. The chlorine containing gas flow path in the vaporizer 100 may be used for supplying other gas species (PH₃, PF₃, BF₃ and N₂, etc.). However, a reaction product generated by the reaction between the aluminum-containing solid material ACM in the crucible 102 and other gas species and other reaction products generated by the reaction between a residual gas and/or a residual vapor in the chlorine containing gas flow path and other gas species may cause unexpected discharge or other disadvantages.

Therefore, it is advantageous to separate a flow path for other gas species from the chlorine containing gas flow path.

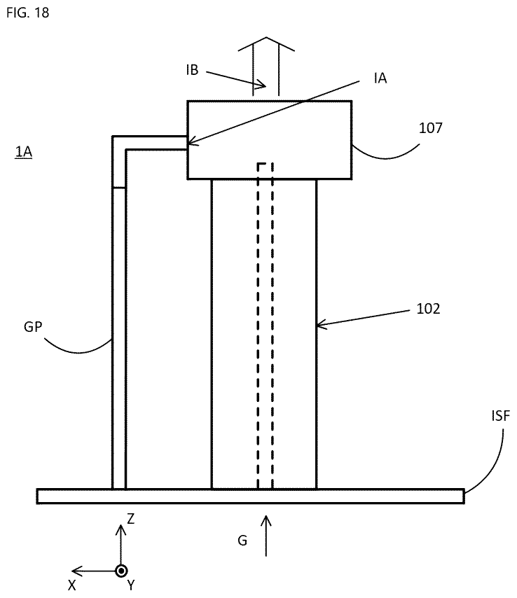

FIG. 18 is a schematic plan view of another example of an ion source, according to various embodiments. In FIG. 18, like reference numbers refer to like elements and a repeated description thereof is omitted for conciseness. As illustrated in FIG. 18, an ion source 1A includes the arc chamber 107 and a crucible 102. The arc chamber 107 is provided with an inlet aperture IA on a side wall of the arc chamber 107 to which an L-shaped gas piping GP is connected to supply other gas species into the arc chamber 107. For example, in some embodiments, the gas of the other species may be supplied from a gas source configured to supply the gas of the other gas species. The specific configuration of the gas source is not particularly limited as long as the gas source is capable of supplying a gas of the other gas species to the gas piping GP and ultimately to the inlet aperture IA.

Returning to FIGS. 3-5, an interior of the vaporizer 100 may be in fluid communication with the interior of the plenum chamber 20 through the nozzle 110. The nozzle 110 of the vaporizer extends through a wall the plenum chamber 20 that is opposite from the plenum plate 40 in the Z-axis direction, and thus a distal portion of the nozzle 110 may extend into the plenum chamber 20.

In the ion source 1 illustrated in FIGS. 3-5, an odd number of the plurality of gas feed chambers 30 are included in the ion source 1. In this case, the vaporizer 100 is offset from the center of the wall of the plenum chamber 20 in the Y-axis direction. The vaporizer 100 may be offset from the center to allow for the gas feed lines 35 to be uniformly spaced along the longitudinal direction (e.g., the Y-axis direction). In other words, the vaporizer 100 may be offset so as not to conflict with one of the gas feed lines 35.

In some embodiments, the ion source 1 may include five gas feed chambers 30 and five gas feed lines 35 as illustrated in FIGS. 3-5. In this case, the vaporizer 100 may be disposed such that two gas feed lines 35 are disposed below the vaporizer 100 and three gas feed lines 35 are disposed above the vaporizer 100 in the Y-axis direction.

The slit 45 of the plenum plate 40 has a geometry based on the location of the nozzle 110 of the vaporizer 100 in the wall of the plenum chamber 20 in the longitudinal direction (e.g., the Y-axis direction). In an embodiment, the slit 45 may include a top portion 46, a transition portion 47, and a bottom portion 48. The top portion 46 has a width in the X-axis direction that is wider than a width of the bottom portion 48 in the X-axis direction. A width of the transition portion 47 in the X-axis direction gradually narrows from the top portion 46 to the bottom portion 48. A location of the nozzle 110 of the vaporizer 100 in the wall of the plenum chamber 20 in the longitudinal direction generally coincides with a location of the transition portion 47 in the slit 45 in the longitudinal direction. In an embodiment, a bottom of the nozzle 110 may be located at a position in the wall of the plenum chamber 20 in the longitudinal direction that corresponds to a top of the transition portion in the longitudinal direction (best seen in FIG. 3). In an embodiment, a distance D1 of the bottom of the nozzle 110 of the vaporizer 100 from a bottom wall of the plenum chamber 20 may correspond to a combined length of the bottom portion 48 and the transition portion 47 of the slit 45 in the Y-axis direction. In an embodiment, a distance D2 of the bottom of the nozzle 110 from a top wall of the plenum chamber 20 may correspond to a distance from the top wall of the plenum chamber 20 to a bottom of the transition portion 47 of the slit 45 in the Y-axis direction. Since the location of the vaporizer 100 is offset from a center of the plenum chamber 20 in the Y-axis direction, the distance D2 from the top wall of the plenum chamber 20 is greater than the distance D1.

In an embodiment, the length in the longitudinal direction of the portion of the slit 45 that has the narrower width may be shorter than a length in the longitudinal direction of the portion of the slit 45 that has the wider width. Thus, assuming a case in which the vaporizer 100 is disposed so as to be offset in the direction of the top wall of the plenum chamber 20 such that two gas feed lines 35 are disposed on top of the vaporizer 100 and three gas feed lines are disposed on the bottom of the vaporizer 100 (i.e., opposite to the example illustrated in FIGS. 3-5), the top portion 46 of the slit 45 would have a narrower width that the bottom portion 48 of the slit 45 (again opposite to the example illustrated in FIGS. 3-5) and the width of the transition portion 47 would gradually decrease from the bottom portion 48 to the top portion 46 (i.e., in the opposite direction to that illustrated in FIGS. 3-5). This configuration is due to the volume of the plenum chamber 20 being less on the side to which the vaporizer 100 is offset such that the portion of the plenum plate 40 with the narrower slit restricts the flow of vapor into the ionization chamber 50 more than the portion of the plenum plate 40 with the wider slit in order that the vapor flows more uniformly into the ionization chamber 50. With the flow of a more uniform vapor along the longitudinal (e.g., the Y-axis direction) into the ionization chamber 50, a more uniform plasma may be generated in the ionization chamber 50 and thus a more uniform ribbon ion beam IB may be extracted from the ionization chamber 50.

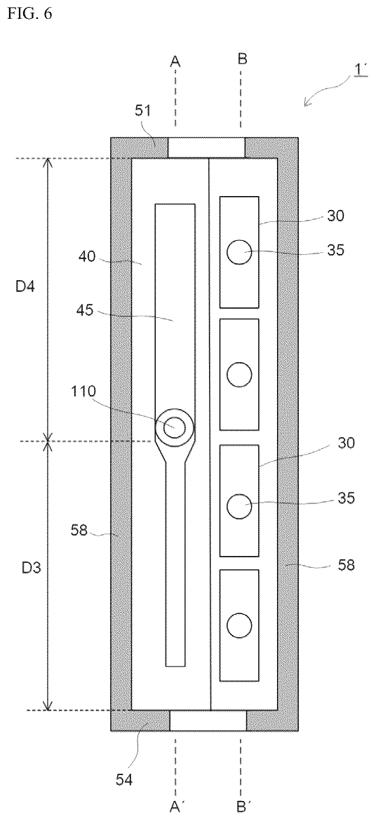

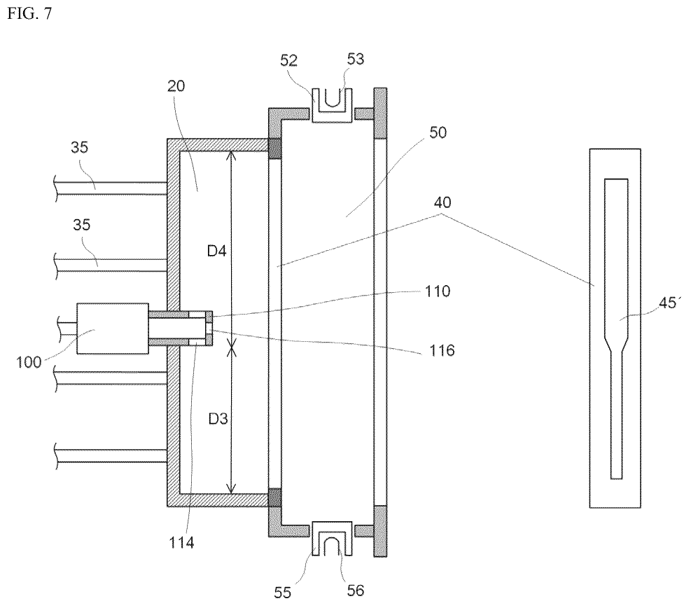

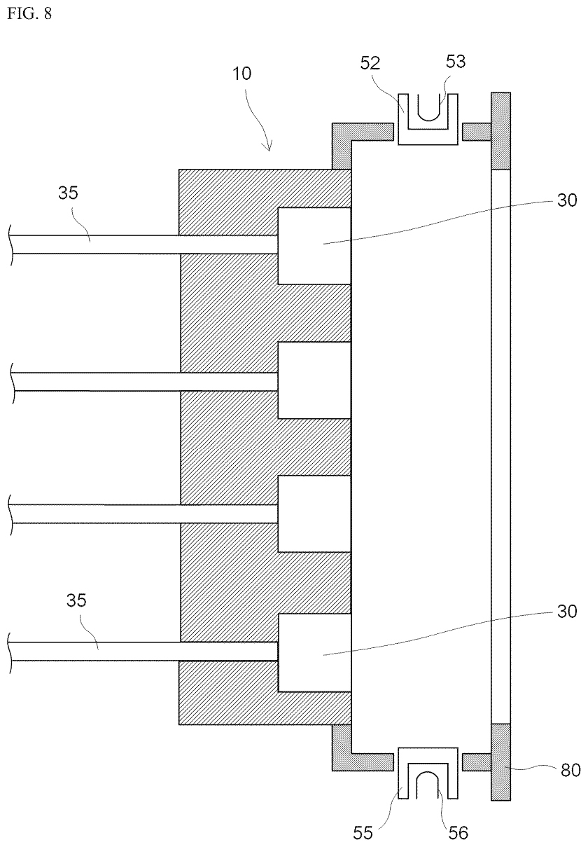

FIGS. 6-8 illustrate a ion source 1′, according to some embodiments, in which FIG. 6 illustrates the ion source 1′ when viewed from a Z-axis direction, FIG. 7 illustrates a cross-sectional view of the ion source 1′ taken along A-A′ in FIG. 6, and FIG. 8 illustrates a cross-sectional view of the ion source 1′ taken along B-B′ in FIG. 6. In FIGS. 6-8, like reference designators represent like components in FIGS. 2-5 that have like structures and functions, and therefore a repeated description thereof is omitted for conciseness.

FIGS. 6-8 illustrate an example in which the plurality of gas feed chambers 30 and the plurality of gas feed lines 35 are each provided in an even number. In this configuration, the vaporizer 100 may be disposed to feed vapor into the plenum chamber 20 at the center of the wall of the plenum chamber 20. For example, FIGS. 6-8 illustrate an example of the ion source 1′ in which four gas feed chambers 30 and four gas feed lines 35 are provided and two of the gas feed lines 35 are positioned above the vaporizer 100 and two of the gas feed lines 35 are positioned below the vaporizer 100. In this case, the nozzle 110 of the vaporizer 100 may be located in the center of the wall of the plenum chamber 20 in the Y-axis direction.

In an embodiment, similar to the example illustrated in FIGS. 3-5, a location of the nozzle 110 of the vaporizer 100 in the wall of the plenum chamber 20 in the longitudinal direction may generally coincide with a location of the transition portion 47 in the longitudinal direction of the slit 45. In an embodiment, a distance D3 of the bottom of the nozzle 110 of the vaporizer 100 from a bottom wall of the plenum chamber 20 may correspond to a combined length of the bottom portion 48 and the transition portion 47 of the slit 45 in the Y-axis direction. In an embodiment, a distance D4 of the bottom of the nozzle 110 from a top wall of the plenum chamber 20 may correspond to a distance from the top wall of the plenum chamber 20 to a bottom of the transition portion 47 of the slit 45 in the Y-axis direction. While, in this example, the location of the vaporizer 100 is at the center of the plenum chamber 20 in the Y-axis direction, the bottom of the nozzle 110 is located below the center and thus the distance D4 from a top wall of the plenum chamber 20 is still greater than the distance D3.

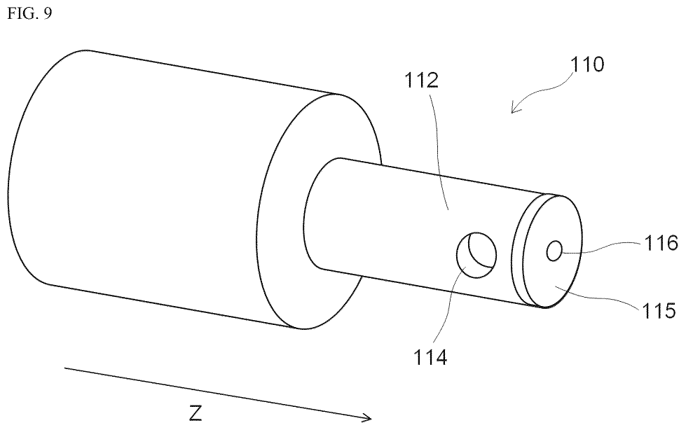

FIG. 9 illustrates an example of a nozzle of a vaporizer of the ion source 1 or the ion source 1′, according to some embodiments. The nozzle 110 may include a pipe 112 and a cap 115 on a distal end of the pipe 112. The pipe 112 may have a plurality of holes 114 formed therein at the distal end of the pipe 112. In an embodiment, two holes 114 may be provided as illustrated in FIG. 9. However, this number is only an example and, in some embodiments, more than two holes 114 may be formed.

In an embodiment, the two holes 114 may be located on opposite sides of the pipe 112. The holes 114 may be located on lateral sides of the pipe 112 (e.g., in the X-axis direction) as illustrated in FIG. 9. However, this location is only an example and, in some embodiments, the holes 114 may be formed in the top and bottom of the pipe 112 (e.g., in the Y-axis direction) (see, e.g., FIG. 4). For example, when the holes 114 are located on the top and bottom of the pipe 112, the vapor may more easily spread out along a longitudinal direction (e.g., the Y-axis direction) in the plenum chamber 20. In an embodiment, a diameter of each of the plurality of holes 114 may be the same. The cap 115 may have a hole 116 formed therein (i.e., in the Z-axis direction). In an embodiment, the diameter of the hole 116 may be smaller than a diameter of each of the holes 114.

In an embodiment, the pipe 112 may extend through the wall of the plenum chamber 20 as described above. As such, a distal portion of the pipe 112 may extend into the plenum chamber 20. In use, a vapor generated from a solid raw material in a crucible (not shown) of the vaporizer 100 may travel through the pipe 112 into the plenum chamber 20 and flow out of the holes 114 and the hole 116 into the plenum chamber 20.

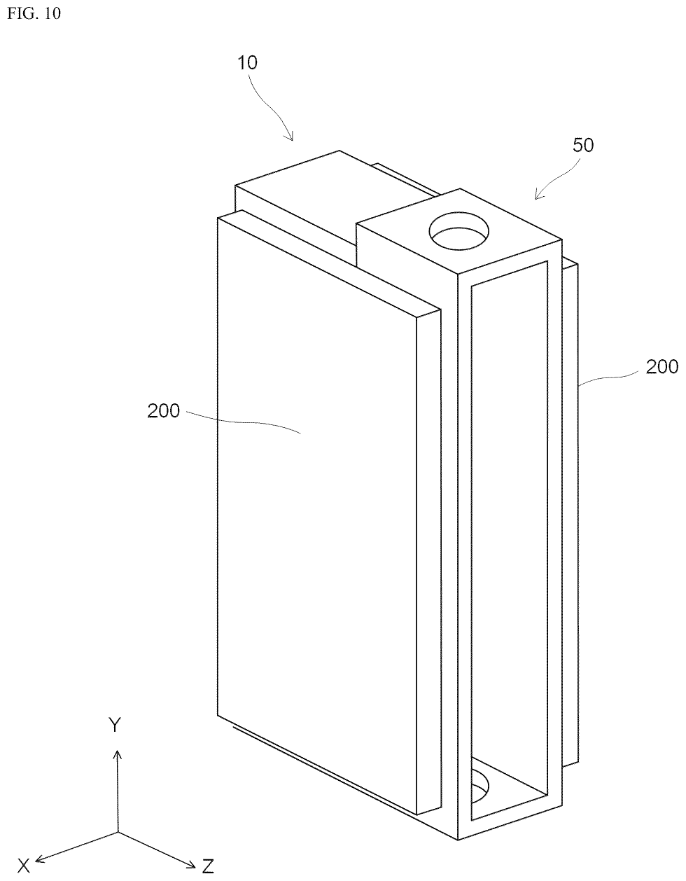

FIG. 10 illustrates an example of a heater of the ion source, according to some embodiments. In an embodiment, a heater 200 may be provided on lateral side surfaces of the plenum 10 and the ionization chamber 50. In an embodiment, the heater 200 may be a block heater as illustrated in FIG. 10. However, embodiments are not limited thereto and, in some embodiments, the heater 200 may be a coil heater. A heater density of the heater 200 at a top and bottom thereof is different than a heater density of the heater 200 at a middle thereof. In other words, the middle of the heater 200 may generate a higher heating temperature than the top and bottom of the heater 200. This is because the cathode 52 and the cathode 55 are provided at the top and the bottom of the ionization chamber 50 and the cathode 52 and the cathode 55 each generate heat. Therefore, for uniform heating, it is not needed to heat the top and bottom ends of the plenum 10 and the ionization chamber 50 as much because the cathode 52 and the cathode 55 provide their own heat. In other words, the heater 200 ensures a uniform temperature of the ionization chamber 50.

In use, the heater 200 helps mitigate condensation of the vapor supplied by the vaporizer 100. For example, in an embodiment, the temperature of the ion source 1 or the ion source 1′ may be very low in comparison with a related art ion source that is used for manufacturing semiconductor devices. As an example, the ion source 1 or the ion source 1′ having a height of about 370 mm to 400 mm and a width of about 60 mm may have a temperature during operation of about 100° C. to about 400° C. By contrast, the related art ion source that is used for manufacturing semiconductor device may have a height of about 130 mm to 160 mm and a width of about 60 mm and may have a temperature during operation of about 1000° C. to about 1500° C. The size of the ionization chamber is only one factor that may determine the temperature of the ionization chamber. Other factors may include, for example, an operation method of the ion source, a structure of the cathode in the ionization chamber, etc.

In some embodiments, the heater 200 may be omitted from the lateral side surfaces of the ionization chamber 50 and the heater 200 may only be provided on the lateral side surfaces of the plenum 10. For example, when a temperature of the ionization chamber 50 is higher than a condensation temperature of the vapor, the heater 200 may be omitted from the lateral side surfaces of the ionization chamber 50.

In some embodiments, the heater 200 may be omitted entirely. For example, when the plenum 10 is heated by heat transfer from the ionization chamber 50 and when the temperature of the plenum 10 is higher than the condensation temperature of the vapor, the heater 200 may be omitted from the ion source 1 or the ion source 1′.

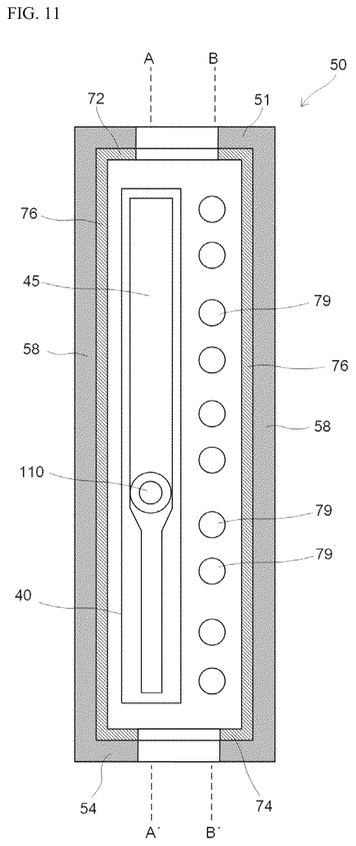

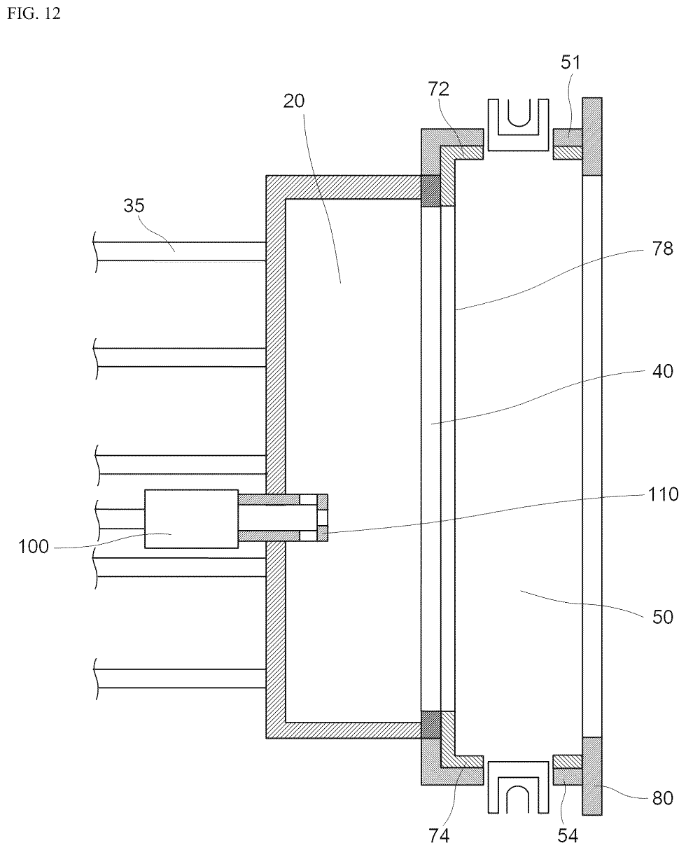

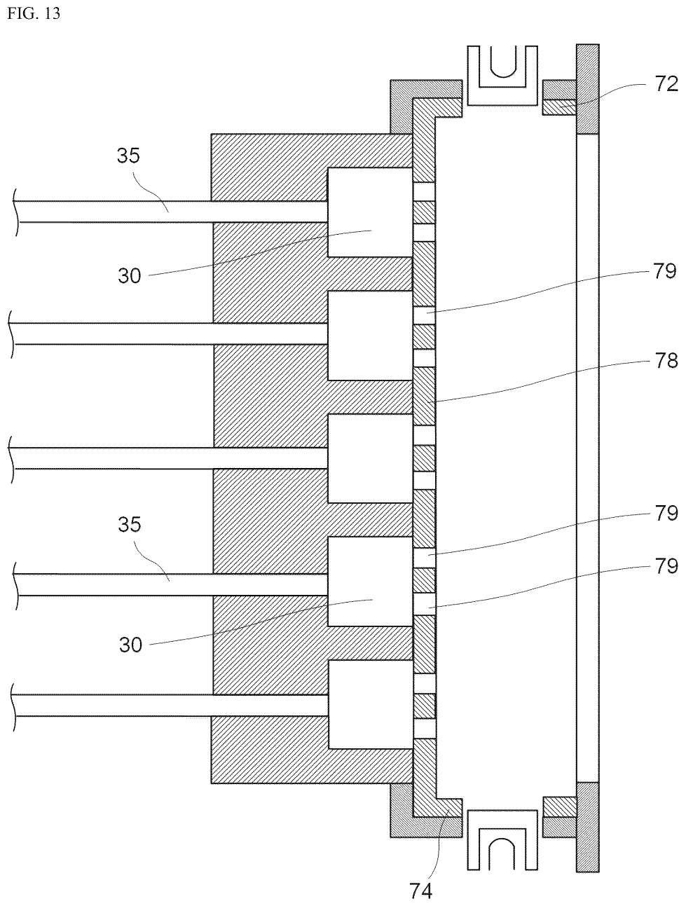

FIGS. 11-13 illustrate a liner of the ion source, according to some embodiments, in which FIG. 11 illustrates the liner when viewed from a Z-axis direction in FIG. 2, FIG. 12 illustrates a cross-sectional view of the liner taken along A-A′ in FIG. 11, and FIG. 13 illustrates a cross-sectional view of the liner taken along B-B′ in FIG. 11.

As described above, in some embodiments, interior walls of the ionization chamber 50 may be covered by the liner 70. In some embodiments, the liner 70 may include the top liner 72, the bottom liner 74, the two side wall liners 76, and the rear liner 78.

As illustrated in FIG. 11, the rear liner 78 may be formed with an opening corresponding to the plenum plate 40 and a plurality of openings 79 for the plurality of gas feed chambers 30. In the example illustrated in FIGS. 11-13, each gas feed chamber 30 is provided with two openings 79 (best seen in FIG. 13). However, embodiments are not limited thereto and, in some embodiments, the rear liner 78 may have one opening 79 or more than two openings 79 for each of the gas feed chambers 30.

In an embodiment, the top liner 72, the bottom liner 74, the two side wall liners 76, and the rear liner 78 may be formed as one single liner 70. However, embodiments are not limited thereto and, in some embodiments, separate liners may be provided.

In an embodiment, the top liner 72, the bottom liner 74, the two side wall liners 76, and the rear liner 78 may each be made of molybdenum. However, this is only an example and, in some embodiments, the top liner 72, the bottom liner 74, the two side wall liners 76, and the rear liner 78 may be made of other materials as long as the material will decrease sputtering onto the walls of the ionization chamber 50.

In some embodiments, the liner 70 may be omitted.

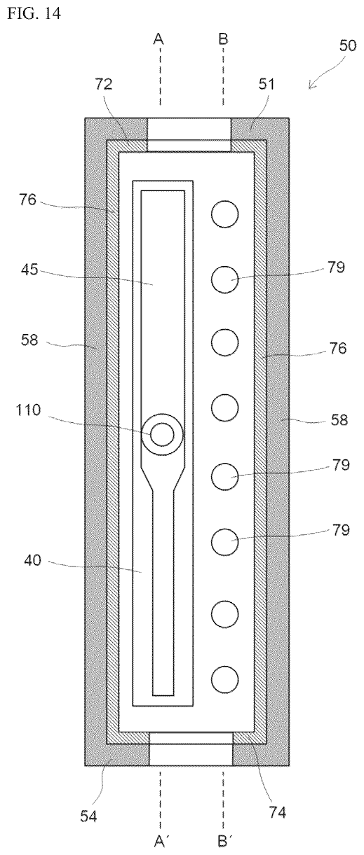

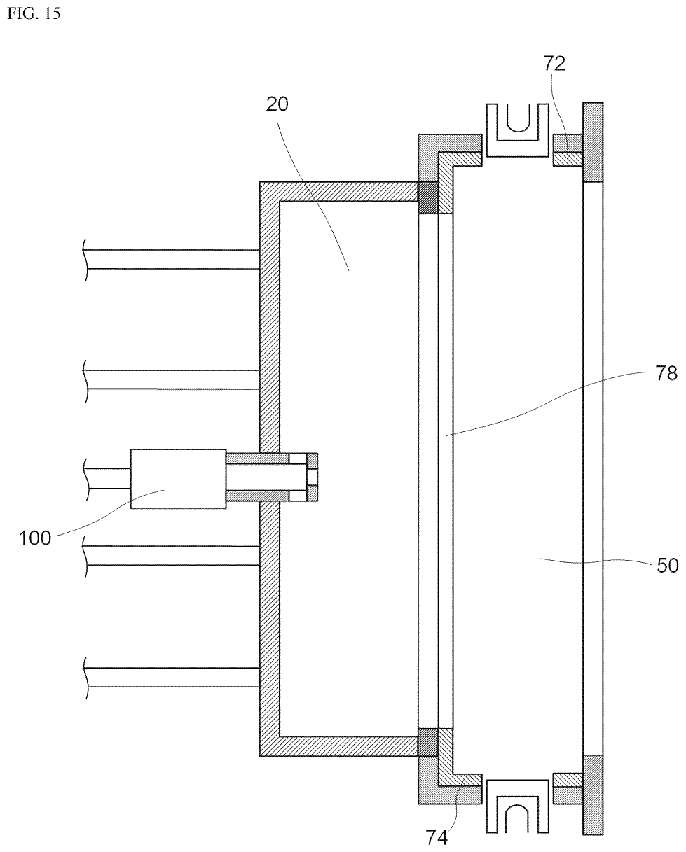

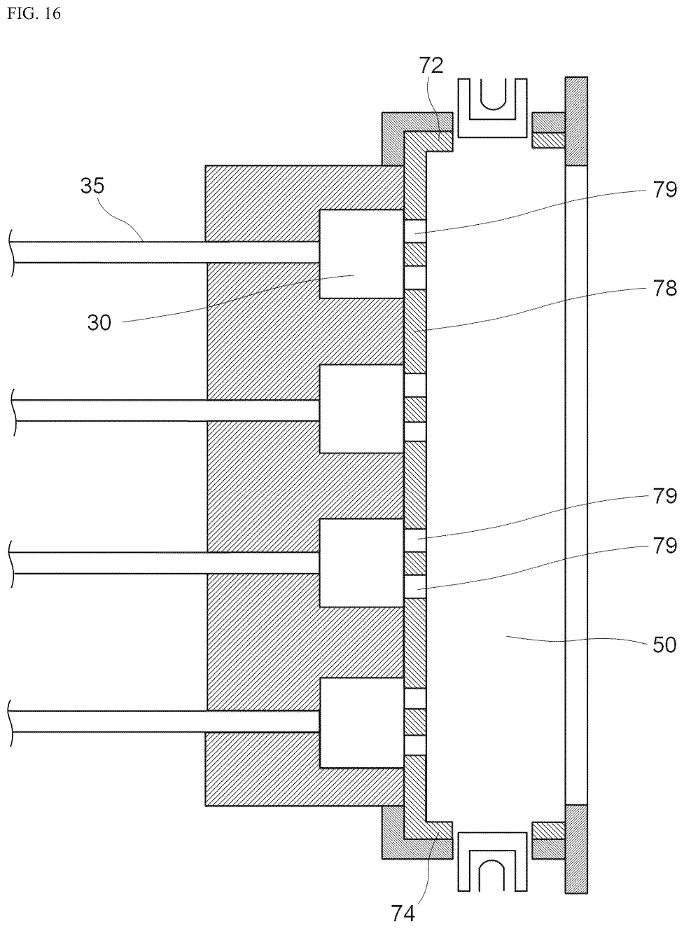

FIGS. 14-16 illustrate a liner of the ion source, according to some embodiments, in which FIG. 14 illustrates the liner when viewed from a Z-axis direction in FIG. 2, FIG. 15 illustrates a cross-sectional view of the liner taken along A-A′ in FIG. 14, and FIG. 16 illustrates a cross-sectional view of the liner taken along B-B′ in FIG. 14. FIGS. 14-16 correspond to FIGS. 13-15 and thus repeated description thereof is omitted for conciseness.

In FIGS. 14-16, an example of the liner 70 as applied to the ion source 1′ of FIGS. 6-8 is illustrated. As with the example illustrated in FIGS. 11-13, the rear liner 78 may include a plurality of openings 79 for the plurality of gas feed chambers 30. In the example illustrated in FIGS. 14-16, each gas feed chamber 30 is provided with two openings 79 (best seen in FIG. 16). However, embodiments are not limited thereto and, in some embodiments, the rear liner 78 may have one opening 79 or more than two openings 79 for each of the gas feed chambers 30.

It should be understood that embodiments are not limited to the various embodiments described above, but various other changes and modifications may be made therein without departing from the spirit and scope thereof as set forth in appended claims.

What is claimed is:

1. A vaporizer comprising:
a crucible in which an solid material is received, the crucible comprising a reactive gas inlet and a vapor outlet.

2. The vaporizer as recited in claim 1, further comprising a heater configured to heat the crucible.

3. The vaporizer as recited in claim 1, wherein the vapor outlet outputs a vapor in a plurality of directions.

4. The vaporizer as recited in claim 1, wherein an edge of the reactive gas inlet is aligned with a surface of the solid material.

5. An ion source comprising:
the vaporizer according to claim 1;
an arc chamber configured to generate a plasma therein,
wherein the vapor outlet of the vaporizer is configured to output the vapor into the arc chamber through a wall of the arc chamber.

6. The ion source as recited in claim 5, wherein the solid material includes at least one of Aluminum, Indium, Titanium, Nickel, Molybdenum, Tungsten, Antinomy, or Sulfur.

7. The ion source as recited in claim 5, wherein the vapor outlet comprises an end portion that extends through the wall of the arc chamber, the end portion comprising a plurality of holes at a distal end thereof.

8. The ion source as recited in claim 5, wherein an edge of the reactive gas inlet is aligned with a surface of the solid material.

9. The ion source as recited in claim 5, wherein the crucible is biased to the arc chamber by an elastic force.

10. The ion source as recited in claim 5, wherein the arc chamber receives the vapor from the vapor outlet of the crucible and receives a gas that does not contain chemical species constituting the solid material from a flow path that does not pass through the crucible.

11. The ion source as recited in claim 5, wherein the arc chamber further comprises a gas inlet communicatively connect to a flow path that does not pass through the crucible.

12. The vaporizer as recited in claim 1, wherein the crucible is cylindrical and extends in a longitudinal direction,
the reactive gas inlet is provided at a first end of the crucible in the longitudinal direction, and
the vapor outlet is provided at a second end of the crucible opposite from the first end in the longitudinal direction.

13. A method for generating a vapor, the method comprising:
preparing a solid material in a crucible; and
introducing a reactive gas into the crucible.

14. A vaporizer comprising:
a first gas source comprising a reactive gas; and
a crucible containing a solid material, the crucible comprising a gas inlet communicatively connected to the first gas source, and a vapor outlet.

15. The vaporizer as recited in claim 14, further comprising a heater configured to heat the crucible.

16. The vaporizer as recited in claim 14, wherein the reactive gas includes chlorine.

17. An ion source comprising:
a first gas source comprising a first gas that contains a reactive component;
a vaporizer comprising a crucible containing a solid material, the crucible comprising a gas inlet communicatively connected to the first gas source, and a vapor outlet; and
an arc chamber configured to generate a plasma therein,
wherein the vapor outlet of the vaporizer is configured to output a vapor into the arc chamber through a wall of the arc chamber.

18. The ion source as recited in claim 17, further comprising:
a second gas source comprising a second gas that does not contain a chemical species constituting the solid material,
wherein the arc chamber comprises a gas inlet communicatively connected to the second gas source, and
wherein a flow path from the second gas source to the gas inlet of the arc chamber does not pass through the crucible.

19. The ion source as recited in claim 17, wherein the reactive component includes chlorine.
